(19) United States
(12) Patent Application Publication
(10) Pub. No.: US 2004/0212041 A1
(43) Pub. Date: Oct. 28, 2004

(54) Semiconductor device and method of manufacturing the same

(75) Inventors: Tomohiro Takamatsu, Kawasaki (JP); Naoya Sashida, Kawasaki (JP); Naoyuki Sato, Yokohama (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: Fujitsu Limited, Kawasaki (JP)

(21) Appl. No.: 10/462,702

(22) Filed: Jun. 17, 2003

(30) Foreign Application Priority Data
Jun. 28, 2002 (JP) 2002-191374

(51) Int. Cl. H01L 29/00

(52) U.S. Cl. 257/534

(57) ABSTRACT

There are provided a first insulating film over a semiconductor substrate, a capacitor formed on the first insulating film and having a lower electrode, a ferroelectric film, and an upper electrode, a capacitor-protection insulating film formed on the capacitor to apply a tensile stress of more than 2.0×10⁹ dyn/cm² to the capacitor, and a second insulating film formed on the capacitor-protection insulating film to apply a compressive stress of more than 2.6×10⁹ dyn/cm² to the capacitor.

### CROSS-REFERENCE TO RELATED APPLICATIONS

This application is based upon and claims priority of Japanese Patent Application No. 2002-191374, filed on Jun. 28, 2002, the contents being incorporated herein by reference.

### BACKGROUND OF THE INVENTION

1. Field of the Invention

The present invention relates to a semiconductor device and a method of manufacturing the same and, more particularly, a semiconductor device having a capacitor and a method of manufacturing the same.

2. Description of the Prior Art

As the nonvolatile memory that can store information after the power supply is turned OFF, the flash memory or the ferroelectric memory (FeRAM) has been known.

The flash memory has the floating gate buried in the gate insulating film of the insulated-gate field effect transistor (IGFET), and stores information by accumulating the charge as stored information in the floating gate. The tunnel current must be passed through the gate insulating film to write/erase the information. Thus, the relatively high voltage is needed.

The FeRAM has the ferroelectric capacitor that stores the information by utilizing the hysteresis characteristic of the ferroelectric substance. In the ferroelectric capacitor, the ferroelectric film formed between the upper electrode and the lower electrode generates the polarization in response to the voltage value applied between the upper electrode and the lower electrode, and has the spontaneous polarization that holds the polarization after the applied voltage is removed. When the polarity of the applied voltage is inverted, the polarity of the spontaneous polarization is also inverted. The information can be read by detecting the polarity and the magnitude of the spontaneous polarization.

The FeRAM has an advantages that it can operate at the lower voltage than the flash memory and the high-speed loading can be achieved while saving a power.

The planar ferroelectric capacitor employed in the memory cell of the FeRAM is formed by steps shown in FIGS. 1A to 1C, for example.

First, as shown in FIG. 1A, a first metal film 103, a ferroelectric film 104, and a second metal film 105 are formed on a first interlayer insulating film 102 that covers a silicon substrate 101. As the ferroelectric film 104, for example, a PZT film is formed. Then, as shown in FIG. 1B, an upper electrode 105a of a capacitor Qₒ is formed by patterning the second metal film 105, and then a dielectric film 104a of the capacitor Qₒ is formed by patterning the ferroelectric film 104. Then, a lower electrode 103a of the capacitor Qₒ is formed by patterning the first metal film 103. Then, as shown in FIG. 1C, the capacitor Qₒ is covered with a second interlayer insulating film 106 made of silicon oxide. Then, a contact hole 106a is formed in the second interlayer insulating film 106 on the upper electrode 104a, and then a leading electrode 108 that is connected to the upper electrode 105a via the contact hole 106a is formed on the second interlayer insulating film 106.

In this case, although not particularly shown, the lower electrode 103a is extruded from the upper electrode 105a in the direction perpendicular to a surface of the sheet, and a leading electrode is formed at the extruded portion via another contact hole.

By the way, it has been known that the polarization characteristic of the ferroelectric capacitor Qₒ is deteriorated when a compressive stress is applied by the second interlayer insulating film 106 formed on the ferroelectric capacitor Qₒ.

In contrast, it is set forth in Patent Application Publication (KOKAI) Hei 11-330390, for example, that the second interlayer insulating film is formed to apply a tensile stress to the ferroelectric capacitor and also the third interlayer insulating film for covering the second interlayer insulating film is formed to have the tensile stress to the ferroelectric capacitor. The second and third interlayer insulating films are made of the silicon oxide film that is formed at the low temperature by using TEOS (tetraethoxysilane) or silane.

Also, it is set forth in Patent Application Publication (KOKAI) 2002-33460 that the ozone TEOS layer is formed on the ferroelectric capacitor and also the silicon oxide film or the primer layer is formed between the ozone TEOS layer and the ferroelectric capacitor. Also, it is set forth that the silicon oxide film, which covers directly the ferroelectric capacitor, has a surface covered with the plasma processing layer, or contains no impurity, or contains at least one of boron and phosphorus. The silicon oxide film or the primer layer, which covers the ferroelectric capacitor, is formed to prevent the deterioration of the ferroelectric capacitor by preventing diffusion of the moisture from the ozone TEOS layer to the ferroelectric capacitor.

In the above prior art, the silicon oxide film formed by using TEOS is formed to apply the tensile stress to the ferroelectric capacitor.

However, according to the experiment of the inventors of the present invention, it become apparent experimentally that, if the silicon oxide film formed by using TEOS is formed to apply the tensile stress as much as possible, an amount of dehydration from the silicon oxide film to the ferroelectric capacitor is increased much more.

Also, according to the experiment of the inventors of the present invention, it is found that, in the memory cell region in which a number of ferroelectric capacitors are provided, the characteristics of the ferroelectric capacitors are different based on difference in positions in the memory cell region. In other words, if the tensile stress is applied to a plurality of ferroelectric capacitors formed in the memory cell region by the interlayer insulating film made of the silicon oxide film, the characteristics of the ferroelectric capacitors become uneven according to the difference in the positions in the memory cell region, or the characteristics of the ferroelectric capacitors in the particular area are deteriorated.

### SUMMARY OF THE INVENTION

It is an object of the present invention to provide a semiconductor device capable of improving characteristics of ferroelectric capacitors formed in plural in a memory cell region, or the like irrespective of their forming positions, and a method of manufacturing the same.

According to one aspect of the present invention, there is provided a semiconductor device comprising: a first insulating film over a semiconductor substrate; a capacitor formed on the first insulating film and having a lower electrode, a ferroelectric film, and an upper electrode; a capacitor-protection insulating film formed on the capacitor to apply a tensile stress of more than 2.0×10⁹ dyn/cm² to the capacitor; and a second insulating film formed on the capacitor-protection insulating film to apply a compressive stress of more than 2.6×10⁹ dyn/cm² to the capacitor.

According to another aspect of the present invention, there is provided a manufacturing method of a semiconductor device comprising the steps of: forming a first insulating film over a semiconductor substrate; forming sequentially a first conductive film, a ferroelectric film, and a second conductive film on the first insulating film; forming a plurality of capacitors by patterning sequentially the first conductive film, the ferroelectric film, and the second conductive film; forming a capacitor-protection insulating film, which applies a tensile stress of more than 2.0×10⁹ dyn/cm² to the capacitors, on the capacitors and the first insulating film; and forming a second insulating film, which applies a compressive stress of more than 2.6×10⁹ dyn/cm² to the capacitors, on the capacitor-protection insulating film.

According to the present invention, the capacitor-protection insulating film that is formed on the capacitor to apply the tensile stress of more than 2.0×10⁹ dyn/cm² to the capacitor and the upper insulating film that is formed on the capacitor-protection insulating film to apply the compressive stress of more than 2.6×10⁹ dyn/cm² to the capacitor are provided.

According to the capacitor-protection insulating film and the upper insulating film having such stress, both the characteristics of the capacitor formed at the end portion of the memory cell region and the capacitor formed in the center of the memory cell region are improved, and thus the characteristics of plural capacitors are made uniform.

### BRIEF DESCRIPTION OF THE DRAWINGS

FIGS. 1A to 1C are sectional views showing steps of forming a ferroelectric capacitor in the prior art;

FIGS. 2A to 2H are sectional views showing semiconductor device manufacturing steps according to an embodiment of the present invention;

FIG. 3 is a plan view showing memory cell regions of a semiconductor device according to the embodiment of the present invention;

FIG. 4 is a view showing a relationship between a film forming power of an interlayer insulating film formed on a capacitor and a stress of the interlayer insulating film, in the semiconductor device according to the embodiment of the present invention;

FIG. 5 is a view showing a relationship between a flow rate of N₂O in a growth gas for the interlayer insulating film formed on the capacitor and the stress of the interlayer insulating film, in the semiconductor device according to the embodiment of the present invention;

FIG. 6 is a view showing a relationship between a flow rate of O₂ in the growth gas for the interlayer insulating film formed on the capacitor and the stress of the interlayer insulating film, in the semiconductor device according to the embodiment of the present invention;

FIG. 7 is a view showing a relationship between a stress of an insulating film formed on a number of capacitors and an amount of average stored charge in a number of capacitors, in the semiconductor device according to the embodiment of the present invention;

FIG. 8 is a view showing a relationship between a stress of an insulating film formed on the capacitor, which is formed at the edge of the memory cell region, and an amount of stored charge in the capacitor, in the semiconductor device according to the embodiment of the present invention;

FIG. 9 is a view showing a relationship between a stress of the interlayer insulating film and an amount of dehydration from the interlayer insulating film, in the semiconductor device according to the embodiment of the present invention;

FIG. 10 is a view showing a relationship between difference in the number of capacitors and an amount of stored charge in the capacitor, when a titanium oxide film is employed as a capacitor-protection insulating film in the semiconductor device according to the embodiment of the present invention;

FIG. 11 is a view showing a relationship between difference in the number of capacitors and an amount of stored charge in the capacitor, when a PZT film is employed as the capacitor-protection insulating film in the semiconductor device according to the embodiment of the present invention;

FIG. 12 is a view showing a relationship between difference in the number of capacitors and an amount of stored charge in the capacitor, when a silicon nitride film is employed as the capacitor-protection insulating film in the semiconductor device according to the embodiment of the present invention;

FIG. 13 is a view showing a relationship between difference in the number of capacitors and an amount of stored charge in the capacitor, when an alumina film is formed at the atmospheric temperature as the capacitor-protection insulating film in the semiconductor device in the prior art;

FIG. 14 is a view showing a relationship between a substrate temperature applied when the alumina film is formed and a stress of the alumina film;

FIG. 15 is a view showing residual dielectric polarization of the capacitor formed at the end portion of the memory cell region respectively when the alumina film formed at the atmospheric temperature is employed as the capacitor-protection insulating film in the semiconductor device in the prior art and when the capacitor-protection insulating film is formed at 350° C. in the semiconductor device according to the embodiment of the present invention; and

FIG. 16 is a view showing magnitudes of a stored charge capacity of the capacitor due to difference in a flow rate of oxygen when the interlayer insulating film is formed on the capacitor-protection insulating film that covers the capacitor, in the semiconductor device according to the embodiment of the present invention.

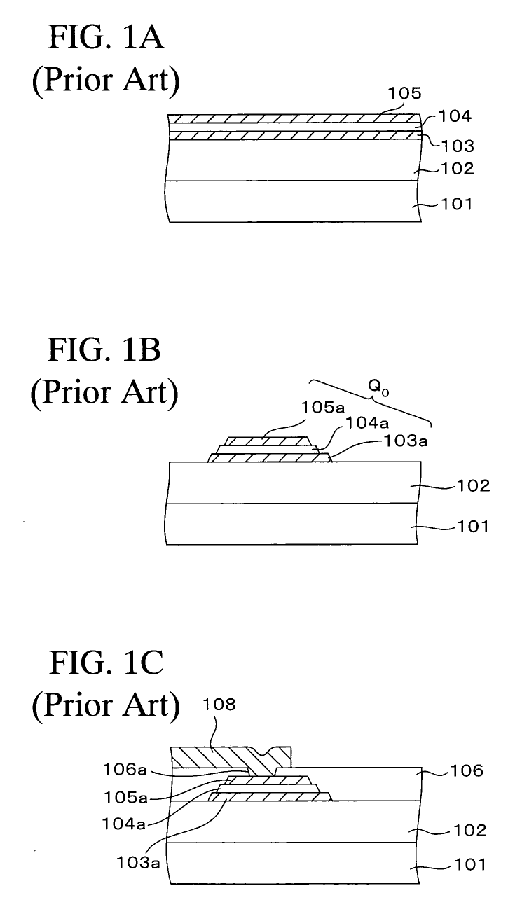

### DESCRIPTION OF THE PREFERRED EMBODIMENT

An embodiment of the present invention will be explained with reference to the drawings hereinafter.

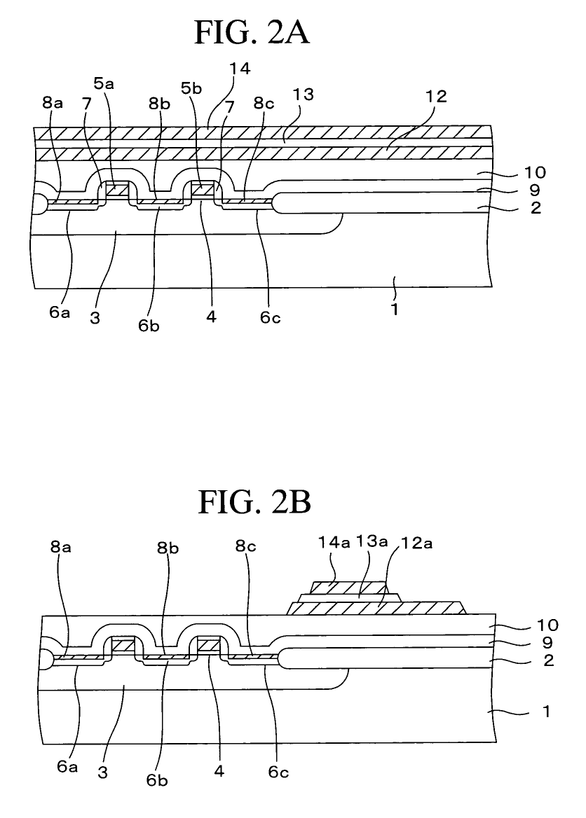

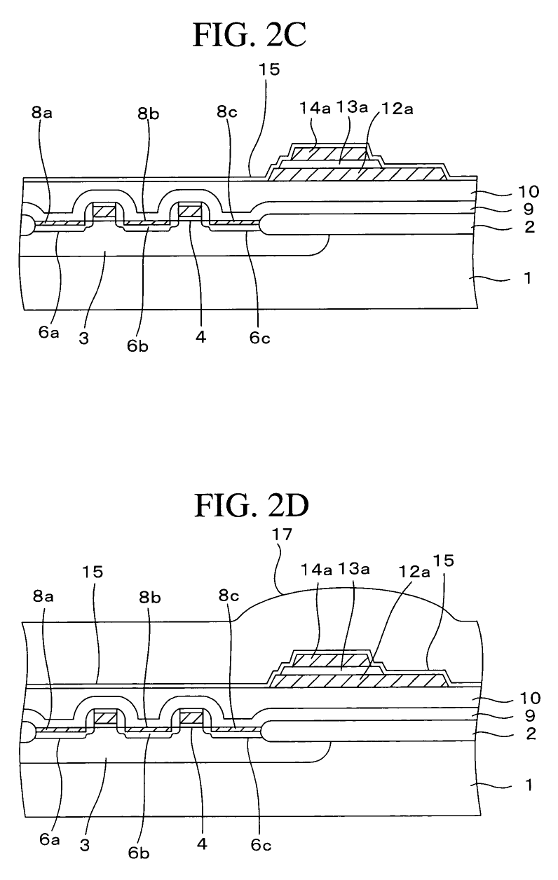

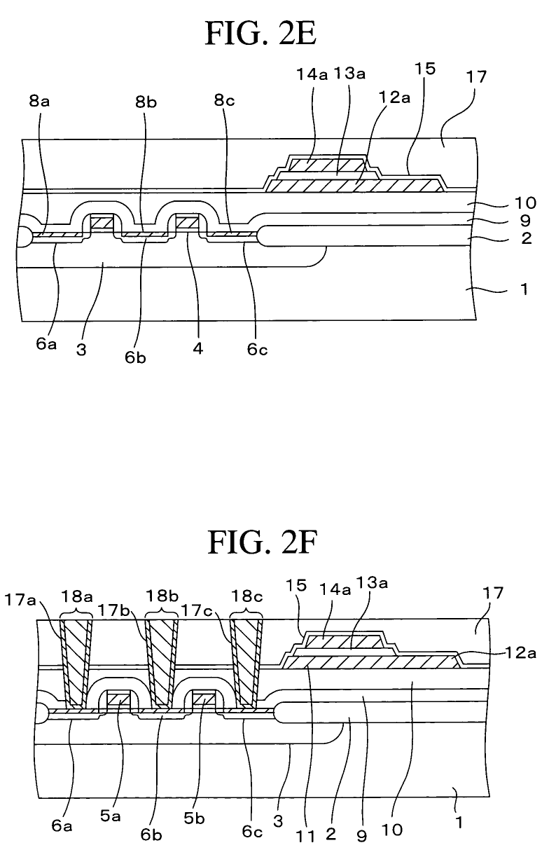

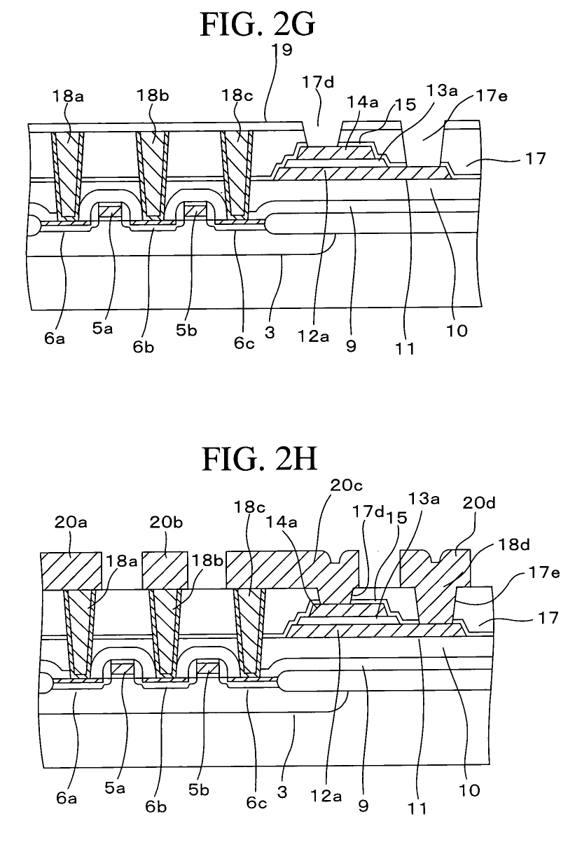

FIGS. 2A to 2H are sectional views showing a semiconductor device manufacturing method according to an embodiment of the present invention in order of step.

Next, steps required until a sectional structure shown in FIG. 2A is formed will be explained hereunder.

First, an element isolation insulating film 2 is formed around an active region (transistor forming region) of an n-type or p-type silicon (semiconductor) substrate 1 by the LOCOS (Local Oxidation of Silicon) method. In this case, the STI (Shallow Trench Isolation) structure may be employed as the element isolation insulating film 2.

Then, p-wells 3 are formed by introducing the p-type impurity into the active regions, which are arranged at an interval vertically and laterally, in the memory cell regions on the silicon substrate 1. Then, silicon oxide films are formed as gate insulating film 4 by thermally oxidizing surfaces of the active regions on the silicon substrate 1.

Then, an amorphous silicon or polysilicon film and a tungsten silicide film are formed sequentially on the overall upper surface of the silicon substrate 1. Then, gate electrodes 5a, 5b are formed by patterning the silicon film and the tungsten silicide film by virtue of the photolithography method.

Two gate electrodes 5a, 5b are arranged in almost parallel at an interval on each p-well 3 in the memory cell region. These gate electrodes 5a, 5b constitute a part of the word line.

Then, n-type impurity diffusion regions 6a to 6c serving as the source/drain of the n-channel MOS transistor are formed by ion-implanting the n-type impurity into the p-well 3 on both sides of the gate electrodes 5a, 5b.

Then, an insulating film is formed on an overall surface of the silicon substrate 1, and then the insulating film is left as a sidewall insulating film 7 only on both side portions of the gate electrodes 5a, 5b by the etching-back. As the insulating film, a silicon oxide (SiO₂), for example, is formed by the CVD method.

Then, the n-type impurity is ion-implanted into the p-wells 3 once again by using the gate electrodes 5a, 5b and the sidewall insulating films 7 as a mask. Thus, the n-type impurity diffusion regions 6a to 6c are formed into the LDD structure.

As described above, a first MOS transistor consisting of the p-well 3, the gate electrode 5a, the first and second n-type impurity diffusion regions 6a, 6b, etc. and a second MOS transistor consisting of the p-well 3, the gate electrode 5b, the second and third n-type impurity diffusion regions 6b, 6c, etc. are formed in the memory cell region. The first and second MOS transistors are formed in plural vertically and laterally in the memory cell region.

Then, a refractory metal film is formed on the overall surface, and then refractory metal silicide layers 8a to 8c are formed on surfaces of the n-type impurity diffusion regions 6a to 6c respectively by heating this refractory metal film. Then, the unreacted refractory metal film is removed by the wet etching. As the refractory metal, there are cobalt, tantalum, etc.

Then, a silicon oxide nitride (SiON) film of about 200 nm thickness is formed as an oxidation-prevention insulating film 9 on the overall surface of the silicon substrate 1 by the plasma CVD method. Then, a silicon dioxide (SiO₂) film of about 1500 nm thickness is grown as a first interlayer insulating film 10 on the oxidation-prevention insulating film 9 by the plasma CVD method using the TEOS gas, or the like. Then, the first interlayer insulating film 10 is thinned by the CMP (Chemical Mechanical Polishing) method to make its surface flat.

Then, a platinum (Pt) film is formed as a first conductive film 12 on the first interlayer insulating film 10 by the sputter method. A thickness of the Pt film is set to about 100 to 300 nm, for example, 150 nm. In this case, a titanium film or a titanium oxide film may be formed under the first conductive film 12. The titanium film or the titanium oxide film is patterned together with the first conductive film 12 in the later step.

The first conductive film 12 is not limited to platinum. A noble metal film such as iridium, ruthenium, etc. or a noble metal oxide film such as ruthenium oxide, strontium ruthenium oxide (SrRuO₃), etc. may be employed.

Then, a PZT (Lead Zirconate Titanate) film of 100 to 300 nm, e.g., 180 nm, thickness is formed as a ferroelectric film 13 on the first conductive film 12 by the sputtering method.

In this case, as the method of forming the ferroelectric film 13, there are the MOD (Metal Organic Deposition) method, the MOCVD (Metal Organic CVD) method, the sol-gel method, etc. in addition to the above. Also, as the material of the ferroelectric film 13, there are other PZT material such as PLCSZT, PLZT, etc., Bi-layered structure compound material such as SrBi₂Ta₂O₉, SrBi₂(Ta,Nb)₂O₉, etc., and other metal oxide ferroelectric substance in addition to PZT.

Then, the PZT film constituting the ferroelectric film 13 is crystallized by applying the RTA (Rapid Thermal Annealing) method in the oxygen-containing atmosphere. As the conditions of RTA, for example, 585°C., 90 second, and the programming rate of 125° C./sec are set. In this case, the oxygen and the argon are introduced into the oxygen-containing atmosphere and an oxygen concentration is set to 2.5%, for example.

Then, an iridium oxide (IrOₓ) film of 100 to 300 nm, e.g., 150 nm thickness is formed as a second conductive film 14 on the ferroelectric film 13 by the sputter method. In this case, a metal film such as a platinum film, a strontium ruthenium oxide (SRO) film, and others may be formed as the second conductive film 14 by the sputter method.

Then, the crystallinity of the ferroelectric film 13 is improved by the RTA executed in the oxygen-containing atmosphere. As the conditions of RTA, for example, 725° C., 20 second, and the programming rate of 125° C./sec are set. In this case, the oxygen and the argon are introduced into the oxygen-containing atmosphere and the oxygen concentration is set to 1.0%, for example.

Next, steps required until a structure shown in FIG. 2B is formed will be explained hereunder.

First, the second conductive film 14 is patterned by the photolithography method while using a first resist pattern (not shown). Thus, an upper electrode 14a of the capacitor Q is formed over the element isolation insulating film 2 near the first and third n-type impurity diffusion regions 6a, 6c.

Then, the first resist pattern is removed, and then the ferroelectric film 13 is annealed at the temperature of 650° C. for 60 minute in the oxygen atmosphere. This annealing is executed to recover a film quality from the damage of the ferroelectric film 13 caused by the sputtering and the etching.

Then, a second resist pattern (not shown) is formed on the upper electrode 14a and its periphery, and then the ferroelectric film 13 is etched by using the second resist pattern as a mask. Thus, the ferroelectric film 13 being left is used as a dielectric film 13a of the ferroelectric capacitor Q. Then, the second resist pattern is removed.

Then, a third resist pattern (not shown) is formed on the upper electrode 14a and the dielectric film 13a and their peripheries. Then, the first conductive film 12 is etched by using the third resist pattern as a mask. Thus, the first conductive film 12 left below the upper electrode 14a is used as a lower electrode 12a of the ferroelectric capacitor Q.

Then, the third resist pattern is removed. Then, the dielectric film 13a is recovered from the damage by executing the annealing at the temperature of 650° C. for 60 minute in the oxygen atmosphere.

As a result, the ferroelectric capacitor Q consisting of the lower electrode 12a, the dielectric film 13a, and the upper electrode 14a is formed on the first interlayer insulating film 10. In this case, the ferroelectric capacitor Q is formed in the memory cell region in plural vertically and laterally.

Then, as shown in FIG. 2C, a capacitor-protection dielectric film 15 that applies the tensile stress to the ferroelectric capacitor Q is formed on the ferroelectric capacitor Q and the first interlayer insulating film 10. As the capacitor-protection dielectric film 15, an insulating film that applise the compressive stress of more than 2.0×10⁹ dyn/cm² to the ferroelectric capacitor Q, for example, a titanium oxide film of 10 to 50 nm thickness, a PZT film of 10 to 50 nm thickness, or a silicon nitride film of 10 to 50 nm thickness, is employed.

Then, as shown in FIG. 2D, a SiO₂ film of about 1600 nm thickness is formed as a second interlayer insulating 17 on the capacitor-protection dielectric film 15. The second interlayer 17 is formed by the plasma CVD method under the conditions that the compressive stress is applied to the ferroelectric capacitor by adjusting a gas flow rate, a plasma generation power, etc. while using TEOS, helium (He), and oxygen (O₂) as the reaction gas. In this case, N₂O may be mixed into the reaction gas.

Then, as shown in FIG. 2E, an upper surface of the second interlayer insulating film 17 is planarized by the CMP method.

Next, steps required until a structure shown in FIG. 2F is formed will be explained hereunder.

First, the first interlayer insulating film 10, the second interlayer insulating film 17, and the capacitor-protection dielectric film 15 are patterned by the photolithography method. Thus, first to third contact holes 17a to 17d are formed on the first to third n-type impurity diffusion regions 6a to 6c in the p-well 3 respectively.

Then, a titanium (Ti) film of 20 nm thickness and a titanium nitride (TiN) film of 50 nm thickness are formed sequentially as an adhesion layer on the second interlayer insulating film 17 and on inner surfaces of the first to third contact holes 17a to 17c by the sputtering method. Then, a tungsten film is formed on the adhesion layer by the CVD method using a mixed gas consisting of tungsten hexafluoride (WF₆) gas, argon, and hydrogen. In this case, the tungsten film has a thickness that burise perfectly the contact holes 17a to 17c.

Then, the tungsten film and the adhesion layer on the second interlayer insulating film 17 are removed by the CMP method to leave only in the contact holes 17a to 17c. Thus, the tungsten film and the adhesion layer left in the contact holes 17a to 17c are used as first to third conductive plugs 18a to 18c respectively.

In this case, in each p-well 3, the second conductive plug 18b formed on the n-type impurity diffusion region 6b, which is put between two gate electrodes 5a, 5b, is connected electrically to the bit line formed thereover whereas the first and third conductive plugs 18a, 18c are connected electrically to the upper electrodes 14a of the ferroelectric capacitors Q via wirings described later.

Next, steps required until a structure shown in FIG. 2G is formed will be explained hereunder.

First, a SiON film of about 100 nm thickness, for example, is formed on the second interlayer insulating film 17 and the first to third conductive plugs 18a to 18c by the plasma CVD method. This SiON film is formed by using a mixed gas consisting of silane (SiH₄) and N₂O, and used as an oxidation preventing film 19 that prevents the oxidation of the first to third conductive plugs 18a to 18c.

Then, the oxidation preventing film 19, the second interlayer insulating film 17, and the capacitor-protection dielectric film 15 are patterned by the photolithography method. Thus, a fourth contact hole 17d is formed on the upper electrode 14a of the capacitor Q and at the same time a fifth contact hole 17e is formed on the lower electrode 12a in the region that is not covered with the upper electrode 14a.

Then, the film quality of the dielectric film 13a is improved by annealing the ferroelectric capacitor Q via the fourth contact hole 17d at 550° C. for 60 minute in the oxygen atmosphere. In this case, the oxidation preventing film 19 prevents the first to third conductive plugs 18a to 18c from oxidizing.

Then, the oxidation preventing film 19 is removed by the dry etching using the CF gas.

Then, a conductive film containing aluminum is formed on the second interlayer insulating film 17 and the conductive plugs 18a to 18c and in the fourth and fifth contact holes 17d, 17e by the sputter method. Then, as shown in FIG. 2H, a wiring 20c for connecting electrically the third conductive plug 18c on the third n-type impurity diffusion region 6c to the upper electrode 14a via the fourth contact hole 17d is formed by patterning the conductive film by means of the photolithography method. At the same time, a conductive pad 20b is formed on the second conductive plug 18b between two gate electrodes 5a, 5b on the p-well 3. Also, another wiring 20d is formed on the lower electrode 12a of the ferroelectric capacitor Q via the fifth contact hole 17e. In addition, a wiring 20a that is connected to the upper electrode of another ferroelectric capacitor (not shown) is formed on the first conductive plug 18a.

Then, a third interlayer insulating film, a second-layer conductive plugs, the bit line, the cover film, etc. are formed, but their details will be omitted herein.

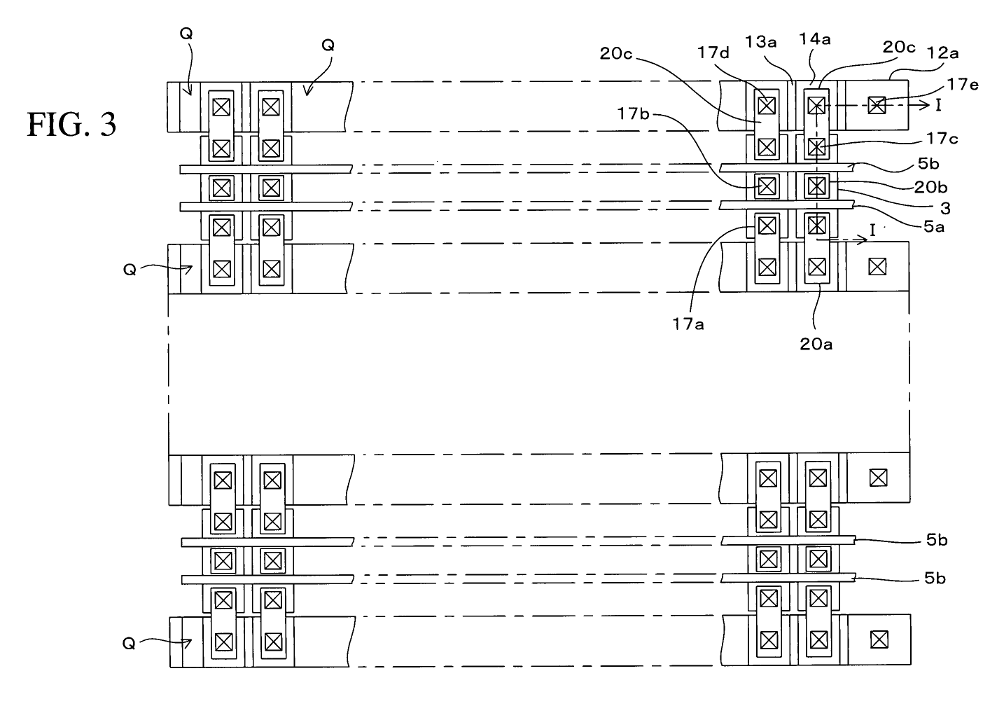

FIG. 3 is a plan view showing arrangement of the p-well 3, the gate electrodes 5a, 5b, the wirings 20a, 20c, the conductive pad 20b, and the capacitor Q in the memory cell of the FeRAM. Also, FIG. 2H is a sectional view when viewed along a I-I line in FIG. 3.

Meanwhile, in the above embodiment, the silicon oxide film is formed as the second interlayer insulating film 17 by using TEOS, etc. Therefore, it was examined how the stress of the silicon oxide film is changed by changing the conditions for forming the silicon oxide film as the second interlayer insulating film 17. In this case, stresses such as the tensile stress, the compressive stress, etc. described in the following are applied to the ferroelectric capacitor Q.

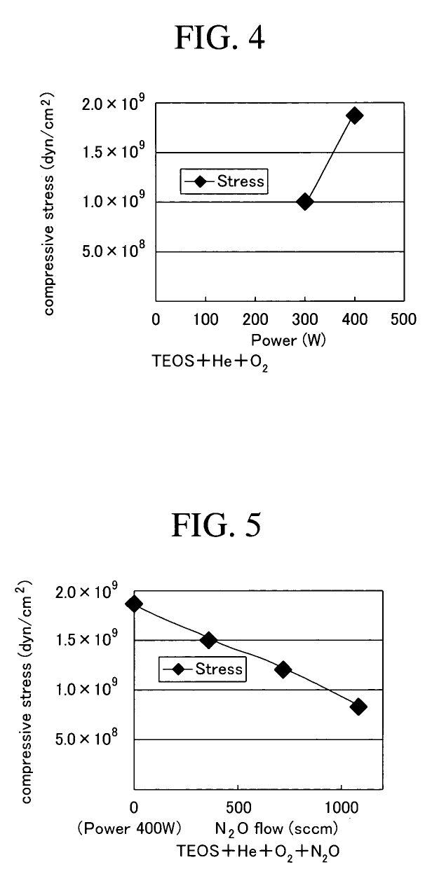

First, a plasma generating power is changed when the silicon oxide film is formed by the plasma CVD method while using the mixed gas consisting of TEOS, He, and O₂ as the reaction gas. At that time, as shown in FIG. 4, the compressive stress of the silicon oxide film is increased as the power is increased.

Also, the mixed gas in which N₂O is added to TEOS, He, and O₂ is employed as the reaction gas, and then a flow rate of N₂O is changed. At that time, as shown in FIG. 5, the compressive stress of the silicon oxide film is reduced as the flow rate of N₂O is increased.

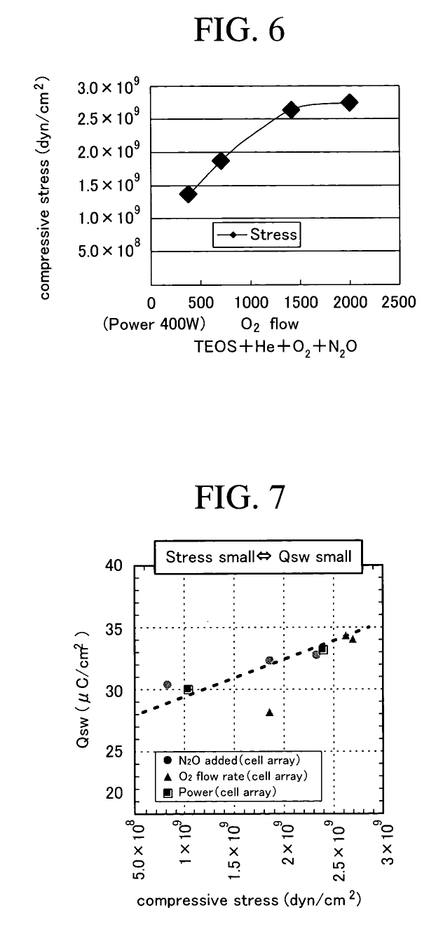

In addition, a flow rate of O₂ is changed when the silicon oxide film is formed by the plasma CVD method while using the gas consisting of TEOS, He, and O₂ as the reaction gas. At that time, as shown in FIG. 6, the compressive stress applied to the silicon oxide film is increased as a flow rate of oxygen is increased.

A relationship between an amount of stored charge Q_{SW} in the ferroelectric capacitor and the stress applied to the ferroelectric capacitor was examined in two types of samples.

A first sample has a first capacitor region in which 1684 ferroelectric capacitors each having a size of 1.6 μm² are formed and which has a total area of 2500 μm². Then, the silicon oxide film (second interlayer insulating film 17) having different compressive stress is formed on these ferroelectric capacitors.

A second sample has a second capacitor region in which 32 ferroelectric capacitors each having a size of 1.6 μm² are formed and which has a total area of 2500 μm². Then, the silicon oxide film (second interlayer insulating film 17) having different compressive stress is formed on these ferroelectric capacitors.

In this case, in the first sample and the second sample, a interval between the ferroelectric capacitors is set to less than 1 μm. Also, the first sample and the second sample are formed on the same substrate at a distance of 840 to 1500 μm, for example.

A large number of ferroelectric capacitors are formed in the memory cell region. However, the capacitor characteristics of the ferroelectric capacitors formed at the edges or their peripheries of the memory cell region are ready to differ from the ferroelectric capacitors formed in the center of the memory cell region.

A plurality of ferroelectric capacitors in the first sample are connected electrically in parallel. Also, a plurality of ferroelectric capacitors in the second sample are connected electrically in parallel.

The first sample is a cell array monitor that is used to average the characteristics of the ferroelectric capacitors that are formed in large numbers in the memory cell region and evaluate them.

The second sample is an end deterioration monitor that is used to evaluate the characteristics of the ferroelectric capacitors corresponding to the end portion of the memory cell region because 20 ferroelectric capacitors out of all 32 capacitors are positioned in the outermost periphery. In the first sample, since the number of the ferroelectric capacitors formed at the end portion is small, the characteristics of the ferroelectric capacitors at the end portion are not evaluated.

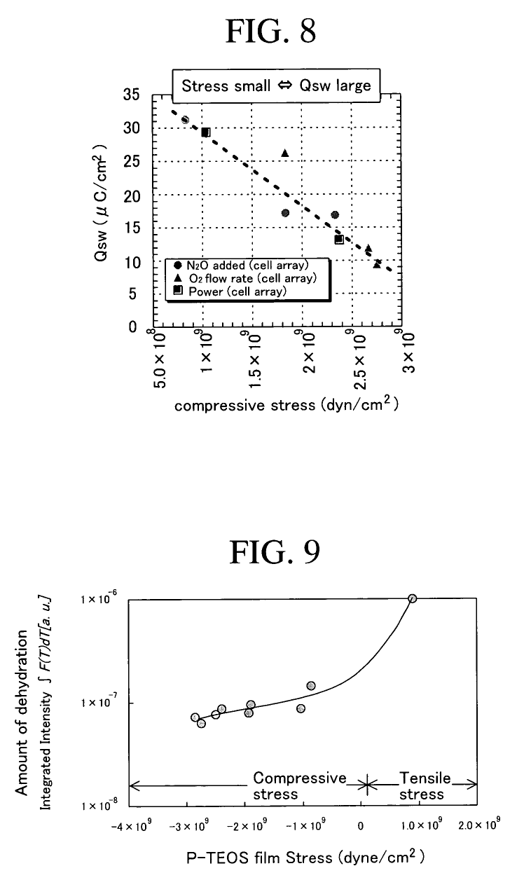

Then, when a relationship between an amount of stored charge Q_{SW} every ferroelectric capacitor and a stress of the silicon oxide film was examined in the first sample, results shown in FIG. 7 were obtained. An amount of stored charge Q_{SW} become smaller as the compressive stress become smaller. Also, when a relationship between an amount of stored charge Q_{SW} every ferroelectric capacitor and a stress of the silicon oxide film was examined in the second sample, results shown in FIG. 8 were obtained. An amount of stored charge Q_{SW} become larger as the compressive stress become smaller.

When a relationship between an amount of dehydration from the silicon oxide film and the stress of the silicon oxide film was examined by the thermal desorption spectroscopy (TDS) method to check the cause of measured results in FIG. 6 and FIG. 7, results shown in FIG. 9 were obtained. In other words, it is appreciated that an amount of dehydration from the silicon oxide film, although varied slightly according to the type of the addition gas, is increased as the stress of the silicon oxide film is being shifted from the compressive stress to the tensile stress. More particularly, it is understood that an amount of dehydration is increased as the value of stress becomes smaller even in the case the compressive stress is applied, and that an amount of dehydration is increased further as the stress becomes larger in the case the tensile stress is applied.

From the above, in FIG. 7, it is appreciated that an amount of stored charge Q_{SW} of the ferroelectric capacitor at the portion of the memory cell region without the edge is subjected largely the influence of the moisture in the second interlayer insulating film 17 rather than the influence of the stress of the second interlayer insulating film 17.

Also, in FIG. 8, it is appreciated that an amount of stored charge Q_{SW} of the ferroelectric capacitor at the end portion of the memory cell region becomes higher as the compressive stress becomes smaller. In other words, in the ferroelectric capacitor formed at the end portion and its perihery of the memory cell region, the capacitor characteristics is improved as the stress applied to the overlying insulating film is changed from the compressive stress to the tensile stress.

As a result, according to FIG. 7, FIG. 8, and FIG. 9, even though the silicon oxide film that is to be formed on the ferroelectric capacitor is formed under the same conditions, the influence of the silicon oxide film on the ferroelectric capacitor is different according to the difference in positions in the memory cell region. Also, it is understood that the ferroelectric capacitor whose characteristic is improved by applying the compressive stress to the insulating film are limited to the case where such capacitors are formed at isolated positions and the case where such capacitors are formed at the edge and its periphery of the memory cell region.

According to the above, it is difficult to suppress the influences of both the stress from the interlayer insulating film and an amount of dehydration from the interlayer insulating film upon the ferroelectric capacitor by merely changing the growth conditions of the interlayer insulating film that covers the ferroelectric capacitor.

For this reason, as shown in FIGS. 2C to 2F, the countermeasure against the degradation of the characteristic of the ferroelectric capacitor Q caused by the stress and the moisture was tried by employing the second interlayer insulating film 17 and the capacitor-protection insulating film 15 in combination.

Such countermeasure is that the capacitor-protection insulating film 15 that can relax the stress applied from the second interlayer insulating film 17 is employed and at the same time the silicon oxide film that has a small amount of dehydration and the large compressive stress is employed as the material constituting the second interlayer insulating film 17. In other words, since the stress of the second interlayer insulating film 17, as shown in FIG. 2C, is applied in the compressive direction, it is desired that the capacitor-protection insulating film 15 should have the large stress in the tensile direction.

As the method of forming the capacitor-protection insulating film 15, there are the method in which the metal film or the amorphous film is formed by the sputter method and then the insulating film is formed by annealing the film in the oxygen atmosphere or the nitrogen atmosphere, and the method of forming the insulating film from the start.

As a first method, there is such a method that the ferroelectric capacitor Q is formed, then a titanium (Ti) film of 20 nm thickness, for example, is formed on the ferroelectric capacitor Q and the first interlayer insulating film 10, and then the titanium film is changed into the titanium oxide (TiOₓ) film by the RTA process executed at 700° C. for 60 second in the oxygen atmosphere. In this case, the Ti film has the compressive stress of 2.0×10⁹ dyn/cm², and the TiOₓ film has the tensile stress of 8.0×10⁹ dyn/cm². Therefore, the stress of the Ti film, when oxidized by the RTA, is changed from the compressive stress to the tensile stress.

As a second method, the ferroelectric capacitor Q is formed, and then the PZT film of 20 nm thickness, for example, is formed on the ferroelectric capacitor Q and the first interlayer insulating film 10 by the RF sputter method. In this case, the PZT is in the amorphous state and the compressive stress of 2.5×10⁹ dyn/cm². Then, the PZT film is crystallized from the amorphous structure to the perovskite structure by the RTA process executed at 700° C. for 60 second in the oxygen atmosphere. The crystallized PZT film has the tensile stress of 7.5×10⁹ dyn/cm². Therefore, the stress of the PZT film is changed from the compressive stress to the tensile stress by the crystallization executed by the RTA process.

As a third method, the ferroelectric capacitor Q is formed, and then the titanium nitride film of 50 nm thickness is formed on the ferroelectric capacitor Q and the first interlayer insulating film 10 by the catalytic CVD method. This titanium nitride film has the tensile stress of 1.5×10¹⁰ dyn/cm².

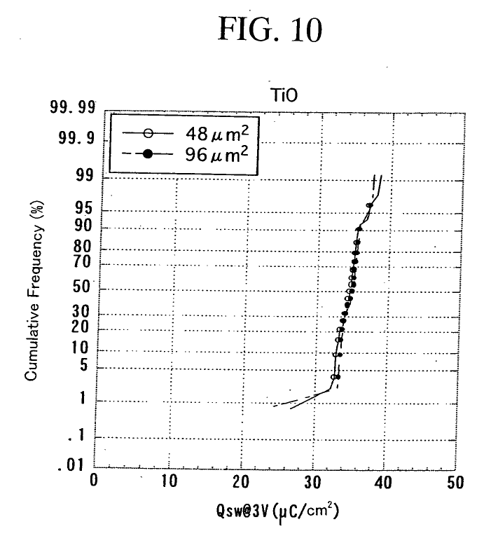

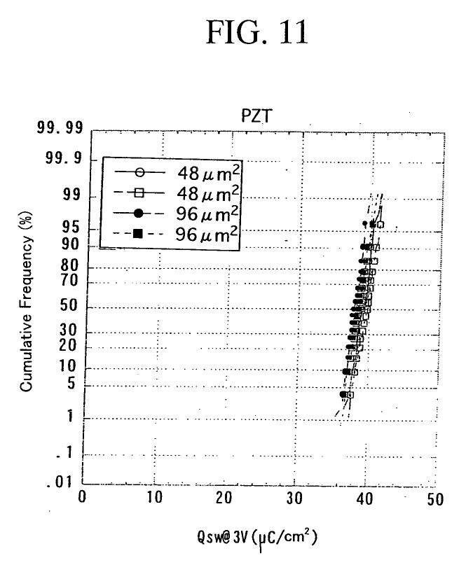

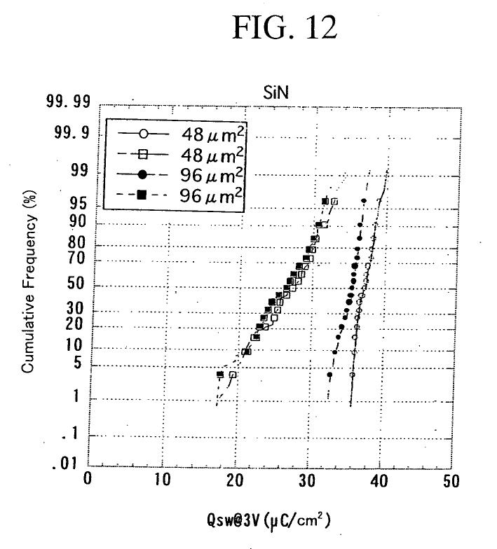

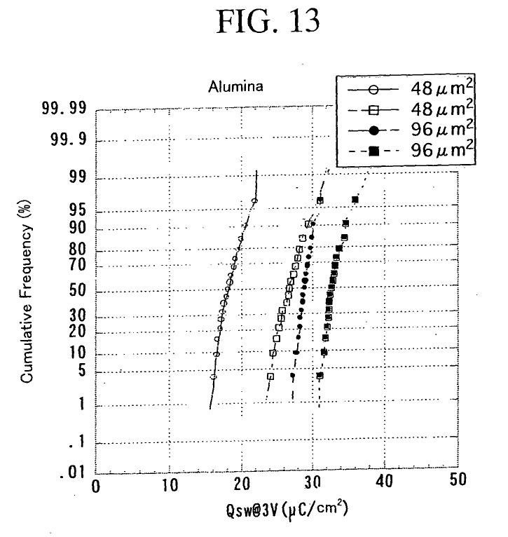

When an amount of stored charge Q_{SW} of the ferroelectric capacitor Q formed under the capacitor-protection insulating film 15 by the first, second and third methods was examined, results shown in FIG. 10, FIG. 11, and FIG. 12 were obtained respectively. In addition, when an amount of stored charge Q_{SW} of the ferroelectric capacitor Q was examined in the state that the alumina film formed at the atmospheric temperature is used as the capacitor-protection insulating film 15, results shown in FIG. 13 were obtained. In this case, in the prior art, the alumina film formed at the atmospheric temperature by the sputter method has the stress of 1.0×10⁹ dyn/cm² in the tensile direction.

In FIG. 10 to FIG. 13, two sheets of silicon substrates, on the same surface of which 71 first end deterioration monitors each having 32 ferroelectric capacitors and having a total area of 48 μm² and 71 second end deterioration monitors each having 64 ferroelectric capacitors and having a total area of 96 μm² are formed, are employed. In other words, the first end deterioration monitors are set to the state that is positioned closer to the edge of the memory cell region than the second end deterioration monitor.

Also, in FIG. 10 to FIG. 13, a cumulative frequency (%) of the measured results of the first and second end deterioration monitors at 71 points on two sheets of semiconductor substrates respectively is denoted on an abscissa, and an amount of stored charge Q_{SW} is denoted on an ordinate. Also, in FIG. 10 to FIG. 13, ◯ indicates the first end deterioration monitor formed on the first silicon substrate, indicates the second end deterioration monitor formed on the first silicon substrate, □ indicates the first end deterioration monitor formed on the second silicon substrate, and ▪ indicates the second end deterioration monitor formed on the second silicon substrate.

In FIG. 13, because four lines are separated, the event that the end deterioration of the ferroelectric capacitor located on the outer peripheral portion of the memory cell region is not sufficiently suppressed is shown.

In contrast, in FIG. 10, because the ◯ line and the line on the first silicon substrate are overlapped with each other, it is appreciated that the effect of suppressing the end deterioration is enhanced by increasing the stress in the tensile direction by using the titanium oxide film. In FIG. 11, because the ◯ line, the ● line, the □ line, and the ▪ line are overlapped with each other, the effect of suppressing the end deterioration is enhanced by increasing the stress in the tensile direction by using the PZT film. Also, in FIG. 12, because the □ line and the ▪ line on the second silicon substrate are overlapped with each other and also the ◯ line and the ● line on the first silicon substrate are overlapped with each other, there is no difference in the deterioration between 48 μm² and 96 μm² respectively, and thus it is appreciated that the effect of suppressing the end deterioration is enhanced by increasing the stress in the tensile direction by using the silicon nitride film.

Based on these results, it is found that, when the tensile stress of the capacitor-protection insulating film 15 is increased higher than the tensile stress of the alumina film formed by the method in the prior art, the effect of suppressing the end deterioration is enhanced and thus the capacitor characteristics is improved.

Meanwhile, normally the substrate temperature is set to the atmospheric temperature in forming the alumina film as the capacitor-protection insulating film 15. If the tensile stress of such alumina film can be increased much more, alumina can be employed as the capacitor-protection insulating film 15.

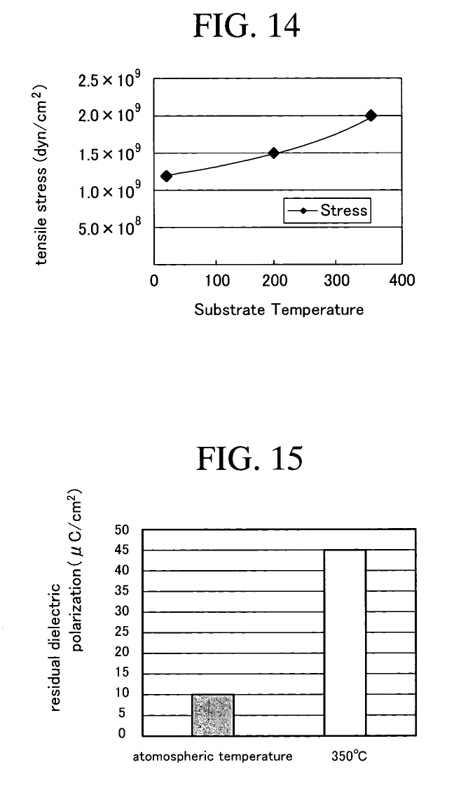

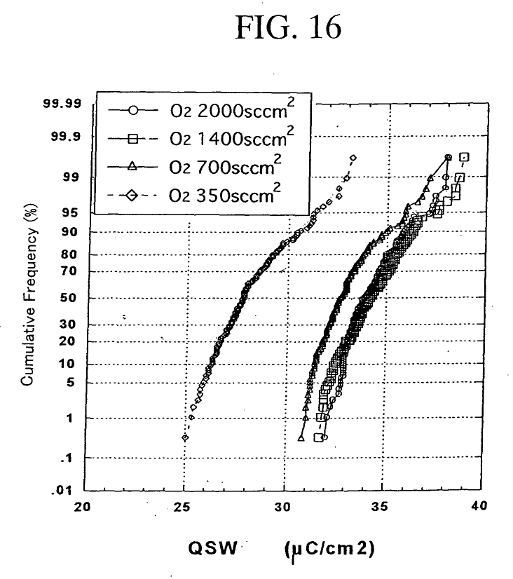

Hence, it was examined whether or not the stress in the tensile stress direction can be changed in the larger direction by changing the film forming conditions of alumina. As the parameter of the film forming conditions, the substrate temperature in the film formation was selected. Then, when a relationship between the substrate temperature in the growth of the alumina film and the stress of the alumina film was examined, results shown in FIG. 14 were obtained. According to FIG. 14, the tensile stress is increased as the substrate temperature is increased, and also the tensile stress of the alumina film is increased about twice when the substrate temperature is changed from the atmospheric temperature to 350° C.

Therefore, when residual dielectric polarization (2Pr) of the ferroelectric capacitor formed under the alumina film are compared each other by comparing the case where the substrate temperature is set to the atmospheric temperature (about 25° C.) in forming the alumina film, which covers the ferroelectric capacitor, with and the case where the substrate temperature is set to 350° C., results shown in FIG. 14 were obtained. It is understood that, in the condition which the alumina film is formed by setting the substrate temperature to more than 350° C., the tensile stress of the alumina film can be increased in excess of 2.0×10⁹ dyn/cm² and thus the effect of suppressing the end deterioration of the capacitor can be generated.

With the above, the film quality of the insulating film employed as the capacitor-protection insulating film 15 must be selected to apply the tensile stress of more than 2.0×10⁹ dyn/cm² to the ferroelectric capacitor, and also the film thickness of such insulating film must be set to less than 50 nm with regard to the selective etching ratio to the second interlayer insulating film 17.

Next, the second interlayer insulating film 17 formed on the capacitor-protection insulating film 15 will be explained hereunder.

As described above, the increase in an amount of dehydration from the second interlayer insulating film 17 formed on the ferroelectric capacitor Q results in the reduction in an average amount of stored charge Q_{SW} in many ferroelectric capacitors Q in the memory cell region. Therefore, it is important that an amount of dehydration from the second interlayer insulating film 17 should be reduced.

In the condition which a flow rate of oxygen is reduced to form the silicon oxide film constituting the second interlayer insulating film 17, the compressive stress of the silicon oxide film is reduced as shown in FIG. 6, but an amount of dehydration is increased as shown in FIG. 8. In the condition which the flow rate of oxygen is increased to form the silicon oxide film, the compressive stress of the silicon oxide film is enhanced, but an amount of dehydration is reduced.

For this reason, the silicon oxide film was formed as the second interlayer insulating film 17 while changing the flow rate of oxygen into 300 sccm, 700 sccm, 1400 sccm, and 2000 sccm. Then, when an amount of stored charge Q_{SW} of the ferroelectric capacitor Q was examined by the cell array monitor, results shown in FIG. 16 were obtained. In this case, the capacitor-protection insulating film 15 formed between the second interlayer insulating film 17 and the ferroelectric capacitor Q is in the state that applies the tensile stress of 2.0×10⁹ dyn/cm² or more to the ferroelectric capacitor Q.

In FIG. 16, it is resulted that, in the condition which the flow rate of oxygen is increased to form the silicon oxide film, an amount of stored charge Q_{SW} is increased but an amount of stored charge Q_{SW} is hardly changed at 1400 sccm or more. Hence, in the condition which the flow rate of oxygen is set to more than 1400 sccm, an amount of moisture in the film is reduced and also is not changed and thus the deterioration of a number of ferroelectric capacitors Q in the memory cell region are not caused.

In this case, the flow rate of oxygen of 1400 sccm means that the flow rate of oxygen exceeds 55 flow rate % of a total flow rate of the reaction gas.

Normally, it is difficult to indicate an amount of moisture in the silicon oxide film quantitatively. Hence, because the stress of the silicon oxide film is in inverse proportion to an amount of moisture in the silicon oxide film, the stress condition of the silicon oxide film is defined by using the stress. Then, unless the second interlayer insulating film 17 formed on the capacitor-protection insulating film 15 has the compressive stress of more than 2.6×10⁹ dyn/cm², it is impossible to say that an amount of moisture is sufficiently reduced. Because, the stress of the silicon oxide film that is formed at the flow rate of oxygen of 1400 sccm is the compressive stress of 2.6×10⁹ dyn/cm².

According to the above, the capacitor-protection insulating film 15 that applies the tensile stress of more than 2.0×10⁹ dyn/cm² to the ferroelectric capacitor Q must be formed and then the second interlayer insulating film 17 that applies the compressive stress of more than 2.6×10⁹ dyn/cm² to the ferroelectric capacitor Q must be formed on the capacitor-protection insulating film 15.

Here, a total stress of the stress of the capacitor-protection insulating film 15 and the stress of the second interlayer insulating film 17, which is applied to the ferroelectric capacitor Q, is derived by the following expression.

Total stress=((stress of the interlayer insulating film)×(film thickness of the interlayer insulating film)+(stress of the capacitor-protection insulating film)×(film thickness of the capacitor-protection insulating film))÷((film thickness of the interlayer insulating film)+(film thickness of the capacitor-protection insulating film))

In this case, the minus stress is applied when the stress of the insulating film is the compressive stress, while the plus stress is applied when the stress of the insulating film is the tensile stress.

Then, if the average film thickness of the second interlayer insulating film 17 on the capacitor Q is assumed as 400 nm and the film thickness of the capacitor-protection insulating film 15 is assumed as 50 nm, a total stress applied to the ferroelectric capacitor Q by the second interlayer insulating film 17 and the capacitor-protection insulating film 15 is the compressive stress of less than 2.0×10⁹ dyn/cm².

As described above, according to the present invention, the capacitor-protection insulating film that is formed on the capacitor to apply the tensile stress of more than 2.0×10⁹ dyn/cm² to the capacitor and the upper insulating film that is formed on the capacitor-protection insulating film to apply the compressive stress of more than 2.6×10⁹ dyn/cm² to the capacitor are provided. Therefore, both the characteristics of the capacitors formed at the end portion of the memory cell region and the characteristics of the capacitors formed in the center of the memory cell region can be improved, and thus the characteristics of plural capacitors can be made uniform.

What is claimed is:

1. A semiconductor device comprising:
a first insulating film over a semiconductor substrate;
a capacitor formed over the first insulating film and having a lower electrode, a ferroelectric film, and an upper electrode;
a capacitor-protection insulating film formed over the capacitor to apply a tensile stress of more than 2.0×10⁹ dyn/cm² to the capacitor; and
a second insulating film formed over the capacitor-protection insulating film to apply a compressive stress of more than 2.6×10⁹ dyn/cm² to the capacitor.

2. A semiconductor device according to claim 1, wherein the capacitor-protection insulating film is formed of any one of alumina, titanium oxide, PZT, and silicon nitride.

3. A semiconductor device according to claim 1, wherein the second insulating film is formed of a silicon oxide film.

4. A semiconductor device according to claim 1, wherein a film thickness of the capacitor-protection insulating film is more than 10 nm but less than 50 nm.

5. A semiconductor device according to claim 1, wherein a total stress applied to the capacitor by the tensile stress of the capacitor-protection insulating film and the compressive stress of the second insulating film is the compressive stress of less than 2.0×10⁹ dyn/cm².

6. A semiconductor device according to claim 5, wherein the capacitor-protection insulating film is formed of any one of alumina, titanium oxide, PZT, and silicon nitride.

7. A semiconductor device according to claim 6, wherein a film thickness of the capacitor-protection insulating film is more than 10 nm but less than 50 nm.

8. A semiconductor device according to claim 5, wherein the second insulating film is formed of a silicon oxide film.

9. A semiconductor device according to claim 1, wherein the capacitor is formed in plural on the first insulating film.

10. A semiconductor device manufacturing method according to claim 1, wherein a transistor that is connected electrically to the capacitor is formed below the first insulating film.

11. A manufacturing method of a semiconductor device comprising the steps of:
forming a first insulating film over a semiconductor substrate;
forming sequentially a first conductive film, a ferroelectric film, and a second conductive film over the first insulating film;
forming a capacitor by patterning sequentially the first conductive film, the ferroelectric film, and the second conductive film;
forming a capacitor-protection insulating film, which applies a tensile stress of more than 2.0×10⁹ dyn/cm² to the capacitor, covering the capacitor and the first insulating film; and
forming a second insulating film, which applies a compressive stress of more than 2.6×10⁹ dyn/cm² to the capacitors, on the capacitor-protection insulating film.

12. A manufacturing method of a semiconductor device according to claim 11, wherein the step of forming the capacitor-protection insulating film is the step of forming an alumina film by a sputter while setting a temperature of the semiconductor substrate to more than 350° C.

13. A manufacturing method of a semiconductor device according to claim 11, wherein the step of forming the capacitor-protection insulating film is the step of forming a titanium oxide film by forming a titanium film on the capacitors and then annealing the titanium film in an oxygen atmosphere.

14. A manufacturing method of a semiconductor device according to claim 11, wherein the step of forming the capacitor-protection insulating film is the step of crystallizing an amorphous insulating film by annealing.

15. A manufacturing method of a semiconductor device according to claim 14, wherein the amorphous insulating film is a PZT film.

16. A manufacturing method of a semiconductor device according to claim 11, wherein the second insulating film is formed by a plasma CVD method while introducing a mixed gas containing TEOS and oxygen in a reaction atmosphere.

17. A manufacturing method of a semiconductor device according to claim 16, wherein the oxygen is introduced into the reaction atmosphere at a 55 flow rate % or more with respect to a total flow rate of the mixed gas.

18. A manufacturing method of a semiconductor device according to claim 16, wherein the second insulating film is formed to have a film quality that applies the compressive stress of more than 2.6×10⁹ dyn/cm² to the capacitor by adjusting the flow rate of oxygen supplied to the reaction atmosphere and a power applied to the mixed gas.

19. A manufacturing method of a semiconductor device according to claim 16, wherein nitrogen is introduced into the mixed gas.

20. A manufacturing method of a semiconductor device according to claim 19, wherein the second insulating film is set to a film quality that applies the compressive stress of more than 2.6×10⁹ dyn/cm² to the capacitors by adjusting an amount of introduced nitrogen.
